(19) United States
(12) Patent Application Publication
(10) Pub. No.: US 2020/0220332 A1
(43) Pub. Date: Jul. 9, 2020

(54) LASER LINE ILLUMINATION USING COMBINED SINGLE-MODE AND MULTI-MODE LASER SOURCES

(71) Applicant: Li-Cor, Inc., Lincoln, NE (US)

(72) Inventors: Irma Nicholls, Lincoln, NE (US); Ahmed Bouzid, Lincoln, NE (US); Christopher Leiak, Lincoln, NE (US)

(21) Appl. No.: 16/734,731

(22) Filed: Jan. 6, 2020

Related U.S. Application Data
(60) Provisional application No. 62/789,094, filed on Jan. 7, 2019.

(51) Int. Cl. H01S 5/40; G02B 27/09; H01S 3/23

(52) U.S. Cl. CPC H01S 5/4012; H01S 5/4087; H01S 3/2391; G02B 27/0927

(57) ABSTRACT

Systems for combining multi-mode (MM) and single-mode (SM) illumination beams of differing wavelengths together and creating a uniform, multi-wavelength laser line at a sample plane with minimal or no loss of optical power. A system includes correction optics configured to reduce the beam waist size of the MM illumination beam to substantially the same size as the beam waist size of the SM illumination beam, and beam-combining optics configured to combine the SM illumination beam and the MM illumination beam into a combined illumination beam along a first light path.

### CROSS REFERENCES TO RELATED APPLICATIONS

This patent application claims priority to U.S. Provisional Patent Application No. 62/789,094, entitled “LASER LINE ILLUMINATION USING COMBINED SINGLE-MODE AND MULTI-MODE LASER SOURCES,” filed Jan. 7, 2019, which is incorporated herein by reference in its entirety.

### SUMMARY

Various embodiments advantageously provide systems and methods for combining multi-mode (MM) and single-mode (SM) illumination beams of differing wavelengths together and creating a uniform, multi-wavelength laser line at a sample plane with minimal or no loss of optical power. In certain embodiments, the systems and methods advantageously enable a longer laser line with uniform energy, e.g., via the use of correction optics.

Various embodiments enable combining beams from two types of lasers, single-mode (SM) laser diodes and multi-mode (MM) laser diodes, to travel down a common path (simultaneously) and to efficiently create a uniform laser line at a sample plane, with minimal loss of optical power from both types of lasers. Embodiments also enable illumination of a sample plane by way of one or multiple single-wavelength or multi-wavelength laser beams passing though the same optical system along the same path with uniform motion. With SM and MM laser beams having varying beam sizes in both the x-direction and the y-direction (transverse to the direction or propagation, or z-direction), the embodiments provide optics that influence the beam size of the MM beam and/or the SM beam to allow for simultaneous use of both MM and SM lasers.

The various embodiments advantageously enable optimized quantitative measurements of the sample plane, e.g., one or more targets of interest at or on the sample plane, which may be applicable for various scientific applications, such as but not limited to fluorescent imaging.

According to an embodiment, a system that combines multi-mode and single-mode illumination beams is provided. For example, the system may include a single-mode laser that outputs an illumination beam having a single-mode profile, and a multi-mode laser that outputs an illumination beam having a multi-mode profile, wherein a beam waist size of the multi-mode profile illumination beam is greater than a beam waist size of the single-mode profile illumination beam. To facilitate combination of multi-mode and single-mode beams, the system includes correction optics configured to substantially match the beam waist sizes of an MM beam and an SM beam. For example, the correction optics may be configured to reduce the beam waist size of the MM illumination beam to substantially the same size as the beam waist size of the SM illumination beam. The system may also include beam-combining optics configured to combine the SM illumination beam and the MM illumination beam into a combined illumination beam along a first light path. In certain aspects, the beam-combining optics may be positioned between the MM laser and the correction optics, and between the SM laser and the correction optics. In certain aspects, the correction optics may be positioned between the MM laser and the beam-combining optics. In certain aspects, the system may include beam-shaping optics configured to reshape a profile of the combined illumination beam to a line-shaped profile at a sample plane. In certain aspects, the beam-shaping optics may include one or more of a cylindrical lens, a Powell lens, an engineered diffuser, a cylindrical micro-lens array and a scanning mirror, or any combination thereof.

In certain aspects, the system may include beam-shaping optics configured to reshape a profile of the combined illumination beam to a spot-shaped profile at a sample plane, and a scanning mirror positioned between the beam-shaping optics and the sample plane and configured to controllably scan the spot-shaped illumination profile to form a line-shaped illumination profile at the sample plane. The spot-shaped illumination profile may be elliptical.

In certain aspects, the correction optics may include one or more of a mirror, a reflective element, a dichroic element, a cylindrical lens, a spherical lens, an aspheric lens, an aperture and a diffractive element, or any combination thereof.

In certain aspects, the illumination beam output by the SM laser may have a wavelength in the visible wavelength range, and the illumination beam output by the MM laser may have a wavelength within the visible to infra-red (IR) wavelength range. It should be appreciated that the SM and the MM lasers may operate at any frequency as desired for the application.

According to another embodiment, a system is provided for producing illumination having a line-shaped profile. The system typically includes one or more SM lasers each configured to output an illumination beam having a SM profile, one or more MM lasers each configured to output an illumination beam having a MM profile, wherein a beam waist size of each of the MM profile illumination beams is greater than a beam waist size of each of the SM profile illumination beams, correction optics configured to reduce the beam waist sizes of the MM illumination beams to substantially the same size as the beam waist size of the SM illumination beams, and beam-combining optics configured to combine the SM illumination beams and the MM illumination beams into a combined illumination beam along a first light path. The system may also include beam-shaping optics configured to reshape a profile of the combined illumination beam to a line-shaped profile at a sample plane.

In certain aspects, the beam-combining optics may be positioned between the one or more MM lasers and the correction optics, and between the one or more SM lasers and the correction optics. In certain aspects, the correction optics may be positioned between the one or more MM lasers and the beam-combining optics.

According to another embodiment, an imaging system is provided that typically includes a sample platform configured to hold a sample that may include one or more targets of interest within or on the sample, and a light source subsystem that illuminates the sample platform. The light source subsystem typically includes a SM laser configured to output an illumination beam having a SM profile, a MM laser configured to output an illumination beam having a MM profile, wherein a beam waist size of the MM profile illumination beam is greater than a beam waist size of the SM profile illumination beam, correction optics configured to reduce the beam waist size of the MM illumination beam to substantially the same size as the beam waist size of the SM illumination beam, beam-combining optics configured to combine the SM illumination beam and the MM illumination beam into a combined illumination beam along a first illumination light path, and beam-shaping optics configured to reshape a profile of the combined illumination beam to a line-shaped profile at the sample platform. The imaging system also typically includes a detector subsystem for detecting light from the sample platform, and having a light detector having an array of sensing locations, and an optical imaging system including optical elements configured to receive light from the sample platform along a first detection light path and to pass or to direct the received light to the light detector along a second detection light path. In certain aspects, the optical imaging system includes a bi-telecentric optical imaging system.

In certain aspects, the systems described herein, including the imaging system, may further include a control system including at least one processor, wherein the control system is communicably coupled with and adapted to control operation of the system components, such as the lasers, light source subsystem, the detector subsystem, various adjustable optical components such as a scanning mirror, adjustable mechanical components, such as mechanical actuators for adjusting or translating physical positions of various components such as optical components, light sources, lasers, a stage or platform that holds a sample that may include one or more targets of interest, etc. In a further embodiment, a non-transitory computer readable medium is provided that stores instructions, which when executed by the at least one processor, causes the at least one processor to control operation of the system components and to implement any method as described herein. Examples of computer readable media include RAM, ROM, CDs, DVDs, ASICs, FPGAs or other circuit elements including memory elements.

In certain aspects, a sample may include one or more targets of interest, and the optical imaging system is configured to image the one or more targets of interest onto the light detector wherein the system is a fluorescence imaging system. In certain aspects, the one or more targets of interest (e.g., within or on a sample, which may be located on a sample platform) may comprise of a fluorescent material, and at least one of the MM illumination beam and the SM illumination beam has a wavelength in an absorption band of the fluorescent material comprised within the one or more targets of interest.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE SEVERAL VIEWS OF THE DRAWING(S)

FIG. 1A shows a profile of a stationary single-mode laser beam at an illumination surface.

FIG. 1B shows a profile of a scanning single-mode laser beam at an illumination surface.

FIG. 1C shows a profile of a stationary multi-mode laser beam at an illumination surface.

FIG. 1D shows a profile of a scanning multi-mode laser beam at an illumination surface.

FIG. 2A shows a profile of a stationary multi-mode laser beam at an illumination surface after correction by the correction optics, according to an embodiment.

FIG. 2B shows a profile of a scanned, corrected multi-mode laser beam at an illumination surface, according to an embodiment.

FIG. 3 illustrates a system for combining multimode and single-mode light beams according to an embodiment.

FIG. 4 illustrates a system for combining multimode and single-mode light beams according to another embodiment.

FIG. 5 illustrates a side view of a bi-telecentric imaging system according to an embodiment.

FIG. 6 illustrates a MM laser beam interacting with correction optics 330 and beam-shaping optics 350 according to an exemplary embodiment.

### DETAILED DESCRIPTION

Various system and method embodiment are provided for combining multi-mode (MM) and single-mode (SM) illumination beams of differing wavelengths together and creating a uniform, multi-wavelength laser line at a sample plane with minimal or no loss of optical power. In certain embodiments, the systems and methods advantageously enable a longer laser line with uniform energy, e.g., via the use of correction optics. It should be understood that “SM illumination beam,” “SM beam” and “SM laser beam” may be used interchangeably herein. Similarly, “MM illumination beam,” “MM beam” and “MM laser beam” may be used interchangeably herein.

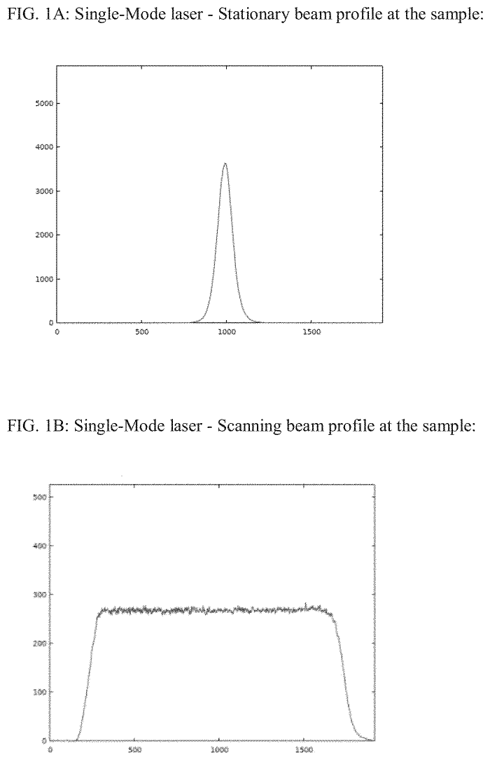

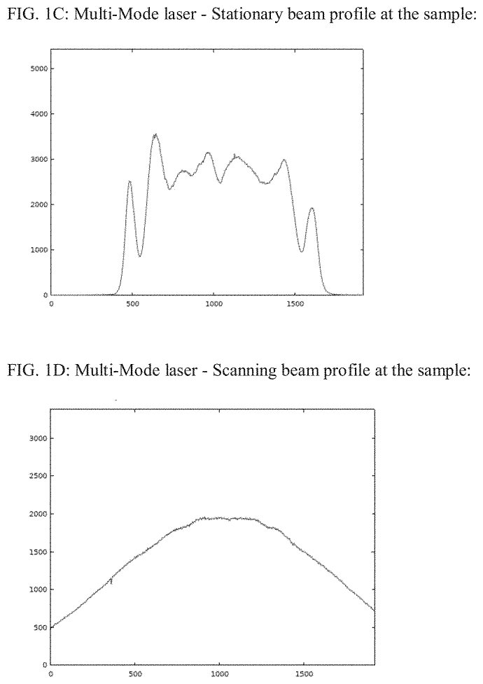

FIG. 1A shows a profile of a stationary SM laser beam at an illumination surface, with brightness (intensity) on the vertical axis and position (or pixel number) on the horizontal axis. The profile shown in FIG. 1A exhibits a typical Gaussian “laser spot” profile at a sample (detection) plane with a peak intensity that diminishes with a Gaussian profile. FIG. 1B shows a profile of a single-mode laser beam profile of FIG. 1A scanned along a single direction at the sample (detection) plane. For example, the laser spot may be scanned using a scanning mirror. The intensity profile shown is substantially uniform along the scan line, creating a substantially uniform laser line at the sample (detection) plane.

FIG. 1C shows a profile of a stationary MM laser beam at an illumination surface, with brightness (intensity) on the vertical axis and position (or pixel number) on the horizontal axis. The profile shown in FIG. 1C exhibits a typical non-uniform MM laser beam profile at a sample (detection) plane with a varying and extended peak intensity relative to a single-mode “laser spot” profile. FIG. 1D shows a profile of the MM laser beam profile of FIG. 1C scanned along a single direction at the sample (detection) plane. For example, the laser beam may be scanned using a scanning mirror. The intensity profile is non-uniform along the scan line, due to the varying and extended “laser spot” of the MM laser. Accordingly, it may be desirable to modify or correct a MM laser beam profile to achieve a more uniform energy profile, e.g., when stationary or when scanned to create a laser line.

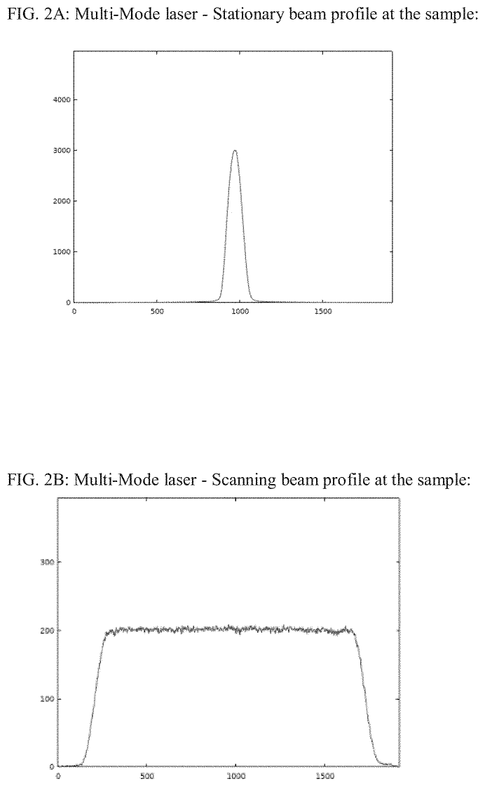

FIG. 2A shows a profile of a stationary MM laser beam at an illumination surface after modification or correction by the correction optics, according to an embodiment, as will be discussed below. FIG. 2B shows a profile of the modified/corrected MM laser beam profile of FIG. 1C scanned along a single direction at the sample (detection) plane, according to an embodiment, as will be discussed below.

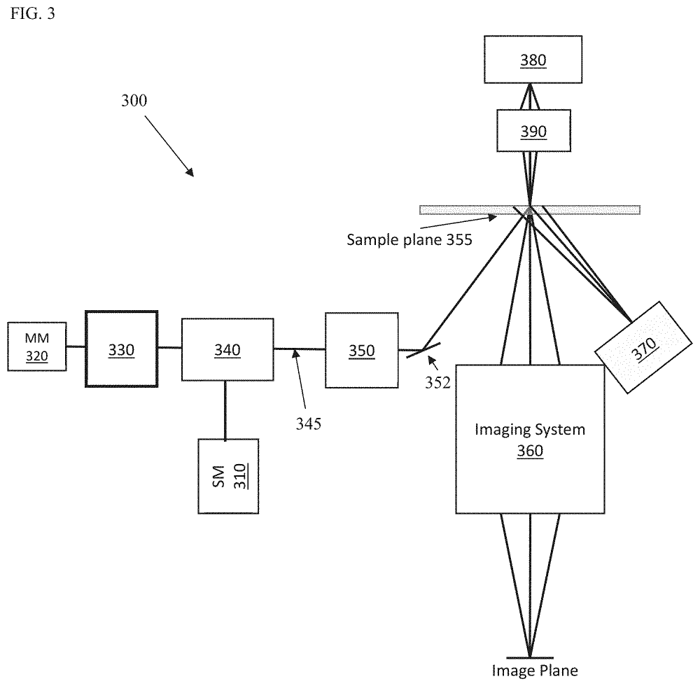

FIG. 3 illustrates a system 300 for combining MM and SM laser beams according to an embodiment. System 300 includes a SM laser 310 that outputs an illumination beam having a SM profile (see, e.g., FIG. 1A), and a MM laser 320 that outputs an illumination beam having a MM profile (see, e.g., FIG. 1C). A beam waist size of the multi-mode laser illumination beam is typically greater than a beam waist size of the SM illumination beam. For example, for a SM laser, the emitting aperture may have a dimension (e.g., diameter) on the order of 1 μm, whereas for a MM laser, the emitting aperture may have a dimension (e.g., diameter) on the order of 100 μm.

Beam correction optics 330 is provided to condition the beam and/or adjust, (e.g., reduce) the beam waist size of the MM illumination beam to substantially the same size as the beam waist size of the SM illumination beam. Beam correction optics 330 may include one or more optical components such as one or more of a mirror, a reflective element, a dichroic element, a cylindrical lens, a spherical lens, an aspheric lens, an aperture and a diffractive element, or any combination thereof, configured to condition the MM beam including adjusting the waist size as needed. Beam-combining optics 340 includes one or more optical components arranged and configured to combine the SM illumination beam and the MM illumination beam conditioned by the beam correction optics 330 into a combined illumination beam 345 along a first light path. Beam combining optics 340 may include one or more of a mirror element, a dichroic element, a prism, a diffractive element such as a grating, a polarization element such as a polarization beamsplitter, or other useful optical components or any combination thereof.

In FIG. 3, the beam correcting optics 330 are placed in the path of the MM laser beam only, e.g., between MM laser 320 and beam-combining optics 340. The SM laser beam output by SM laser 310 does not interact with the beam correcting optics 330 in this embodiment. The MM laser beam output by MM laser 320 may diverge before the beam correcting optics 330 and is focused as needed by the beam correcting optics 330.

As further shown in FIG. 3, system 300 may further include beam-shaping optics 350 configured to reshape a profile of the combined illumination beam 345 to a spot-shaped profile or a line-shaped profile at a sample plane 355. A spot-shaped illumination profile may be circular or elliptical. The beam-shaping optics 350 may include one or more of a cylindrical lens, a Powell lens, an engineered diffuser, a cylindrical micro-lens array, a mirror, or any combination thereof. For example, the beam-shaping optics 350 is configured to reshape a profile of the combined illumination beam 345 to a spot-shaped profile or a line shaped profile at the sample plane 355 (e.g., using an internal scanning mirror to scan a spot-shaped profile beam, or other elements to directly produce a line-shaped profile beam). In an embodiment as shown in FIG. 3, an optional external scanning mirror 352 is provided to controllably redirect and scan a spot-shaped illumination profile produced by beam-shaping optics 350 to form a line-shaped illumination profile at the sample plane 355. In this manner, the MM component of the combined illumination beam impinging on the sample plane 355 may look like the profile as shown in FIG. 2B; the SM component of the combined illumination beam impinging on the sample plane 355 may look like the profile as shown in FIG. 1B, thereby providing a substantially uniform-energy, multi-wavelength laser line profile at the sample plane 355.

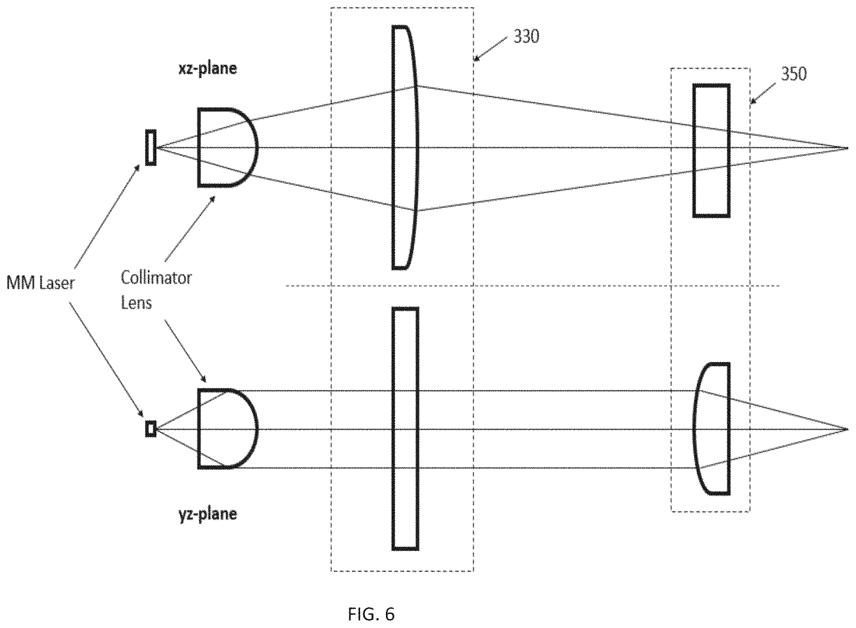

FIG. 6 illustrates a MM laser beam interacting with correction optics 330 and beam-shaping optics 350 according to an exemplary embodiment. The top portion of FIG. 6 illustrates the interaction of the MM beam with the optical elements in the X-Z plane (where Z is the direction of propagation) and the bottom portion of FIG. 6 illustrates the interaction of the MM beam with the optical elements in the Y-Z plane. In this embodiment, a collimator lens element collimates the MM beam emitted by the MM laser and the correction optics operates to focus the MM beam as desired. Beam-shaping optics 350 reshapes the profile of the MM beam to a spot-shaped profile in the embodiment shown.

System 300 also includes, in certain embodiments, an imaging system 360 configured to image sample plane 355. In certain embodiments, system 300 may operate as a multi-modality illumination and imaging system. For example, one or more targets of interest located on sample plane 355 may be illuminated by illumination source 380 (e.g., an LED or other illumination source) in a trans-illumination mode and/or by illumination source 370 (e.g., an LED or other illumination source) in an epi-illumination mode at specific wavelengths and/or by (epi-)laser-line illumination using SM laser 310 and/or MM laser 320 in spot-illumination or line-illumination modes. Optional beam-shaping optics 390 is provided to condition and focus/shape light emitted by illumination source 380 onto sample plane 355 as desired. Imaging system 360 may include a microscope or other optical components configured to image some or all of the sample plane 355 onto an image plane. Imaging system 360 may also include various spectral filters to selectively image spectral content as desired. In certain embodiments, as described below, imaging system 360 may include a bi-telecentric optical imaging system.

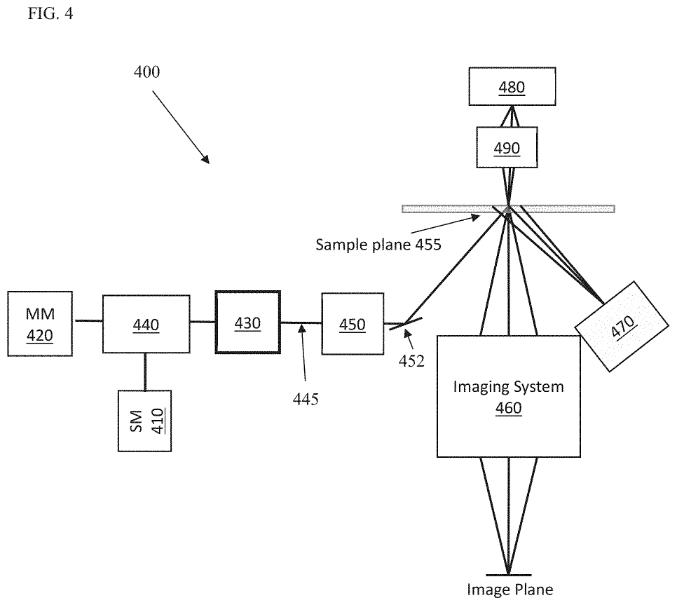

FIG. 4 illustrates a system 400 for combining MM and SM light beams according to another embodiment. System 400 includes a SM laser 410 that outputs an illumination beam having a SM profile (see, e.g., FIG. 1A), and a MM laser 420 that outputs an illumination beam having a MM profile (see, e.g., FIG. 1C). Beam-combining optics 440 combines the SM illumination beam and the MM illumination beam into a combined illumination beam 445 along a first light path. The beam-combining optics 440 may include one or more optical components positioned in an optical path between the MM laser 420 and the correction optics 430, and also in an optical path between the SM laser 410 and the correction optics 430. Beam combining optics 440 may include one or more of a mirror element, a dichroic element, a prism, a diffractive element such as a grating, a polarization element such as a polarization beamsplitter, or other useful optical components or any combination thereof. Beam correction optics 430 is provided along the first beam path to condition the combined illumination beam 445 and/or adjust, (e.g., reduce) the beam waist size of the MM illumination beam component to substantially the same size as the beam waist size of the SM illumination beam component. Beam correction optics 430 may include one or more of a mirror, a reflective element, a dichroic element, a cylindrical lens, a spherical lens, an aspheric lens, an aperture and a diffractive element, or any combination thereof, configured to condition the combined illumination beam 445 including adjusting the waist size of the MM component as needed. The SM beam component travels in parallel rays before interacting with the beam correction optics 430 and is only minimally affected, or unaffected, by the beam correcting optics 430. The MM beam component may diverge before the beam correcting optics 430 and is conditioned and focused as needed by the beam correcting optics 430.

As further shown in FIG. 4, system 400 may further include beam-shaping optics 450 configured to reshape a profile of the combined illumination beam 445 to a spot-shaped profile or a line-shaped profile at a sample plane 455. A spot-shaped illumination profile may be circular or elliptical. The beam-shaping optics 450 may include one or more of a cylindrical lens, a Powell lens, an engineered diffuser, a cylindrical micro-lens array, a mirror, or any combination thereof. For example, the beam-shaping optics 450 is configured to reshape a profile of the combined illumination beam 445 to a spot-shaped profile or a line shaped profile at the sample plane 455 (e.g., using an internal scanning mirror to scan a spot-shaped profile beam, or other elements to directly produce a line-shaped profile beam). In an embodiment as shown in FIG. 4, an optional scanning mirror 452 is provided to controllably scan a spot-shaped illumination profile to form a line-shaped illumination profile at the sample plane 455. In this manner, the MM component of the combined illumination beam impinging on the sample plane 455 may look like the profile as shown in FIG. 2B; the SM component of the combined illumination beam impinging on the sample plane 455 may look like the profile as shown in FIG. 1B, thereby providing a substantially uniform-energy, multi-wavelength laser line profile at the sample plane 455.

System 400 also includes, in certain embodiments, an imaging system 460 configured to image sample plane 455. In certain embodiments, system 400 may operate as a multi-modality illumination and imaging system. For example, one or more targets of interest located on sample plane 455 may be illuminated by illumination source 480 (e.g., an LED or other illumination source) in a trans-illumination mode and/or by illumination source 470 (e.g., an LED or other illumination source) in an epi-illumination mode at specific wavelengths and/or by (epi-)laser-line illumination using SM laser 410 and/or MM laser 420 in spot-illumination or line-illumination modes. Optional beam-shaping optics 490 is provided to condition, and focus/shape light emitted by illumination source 480 onto sample plane 455 as desired. Imaging system 460 may include a microscope or other optical components configured to image some or all of the sample plane 455 onto an image plane. Imaging system 460 may also include various spectral filters to selectively image spectral content as desired. In certain embodiments, as described below, imaging system 460 may include a bi-telecentric optical imaging system.

It should be appreciated that the SM and MM lasers in systems 300 and 400 may be simultaneously operational, or may operate at different times so as to create substantially uniform-in-energy laser line profiles of a single wavelength or multiple wavelengths. It should also be appreciated that multiple SM lasers and/or multiple MM lasers may be combined into a single combined illumination beam using one or more mirror elements to redirect additional beams into the beam path of other beams. For example, one or more second SM beams generated by one or more additional SM lasers may be combined into the beam path of the SM laser (310, 410) prior to interaction with the beam combining optics (340, 440). Similarly, one or more second MM beams generated by one or more additional MM lasers may be combined into the beam path of the MM laser (320, 420) prior to interaction with the beam-shaping optics (330, 430). In some embodiments, two (or more) MM laser beams may be combined without any SM beams; similarly, in some embodiments, two (or more) SM laser beams may be combined without any MM beams. For example, one MM beam may be shaped to better match properties of a second MM beam, or two different MM beams may be shaped differently, and the MM beams combined prior to interacting with the sample platform. The SM laser(s) and the MM laser(s) may operate in any desired wavelength range. For example, in certain embodiments, the SM laser(s) may operate in a visible wavelength range, and the MM laser(s) may operate within a visible to infra-red wavelength range.

In some embodiments, the beam waist size of a SM laser beam may be adjusted to match the beam waist size of a MM laser beam. For example, correction optics (e.g., 330, 430) may be positioned in the path of an output SM laser beam but not the path of an output MM laser beam. In such embodiments, a SM beam may be expanded, rather than reducing a size of a MM beam. In some embodiments, separate correction optics may be used to condition MM and SM beams separately. For example, a SM beam may be expanded in size and a MM beam may concomitantly be reduced in size so that the beam waist sizes of the MM and SM beams substantially match.

In some embodiments, a neutral density (ND) filter may be used to reduce the intensity of the laser illumination interacting with the sample platform. For example, a neutral density filter may be automatically inserted into the path of the combined laser beam, e.g., either before scanning mirror 352, 452 or after scanning mirror 352, 452, using a filter wheel or other controllable motorized mechanism or actuator as is known to one skilled in the art. For example, in response to a control signal received from the control system, the filter wheel or other controllable motorized mechanism or actuator moves the ND filter in or out of the first light path between the scanning mirror and the sample platform. Use of a ND filter may enable the expansion of the dynamic range detectable by the sensor or detector used. For example, a first pass or scan of the combined laser beam over the sample platform may be performed with (or without) the ND filter in place, followed by a second pass or scan without (or with) a ND filter in place. The image(s) obtained during the higher illumination intensity scan (without ND filter) may be combined with the image(s) obtained during the lower illumination intensity scan (with ND filter in the beam path) to produce combined image(s) of the sample platform, the sample or one or more targets of interest. In some embodiments, different scans may be performed using different ND filters of varying strength. In this manner, different intensity-level scans may be performed without having to adjust sensor/detector gain or use different sensors and without having to adjust the output intensity of any laser.

In some embodiments, it may be desirable to reduce the added exposure of the sample platform to the combined laser beam during periods when the scanning mirror (352, 452) is reversing the direction of the scan. For example, as the galvo-mirror changes from scanning the beam in one direction to scanning in the opposite direction, the added dwell time of the laser beam during this turnaround time at the scan turnaround location on the sample platform may adversely impact any sample on the sample platform or images of the sample. To reduce or eliminate any effects the turnaround time may cause, e.g., to reduce or eliminate exposure of the sample to the combined beam during the turnaround period, in one embodiment, an aperture block may be used. In this embodiment, an aperture of appropriate dimension is placed in the path of the combined beam between the scanning mirror 352, 452 and the sample platform 355, 455, to physically restrict the combined laser beam during the turnaround period from illuminating the sample platform; e.g., during the turnaround time, the combined laser beam interacts with the physical material defining the aperture therein. In another embodiment, the laser may be controlled to turn off during the turnaround time.

The uniform, multi-wavelength laser lines that may be generated in the embodiments described herein are particularly useful with wide-field imaging systems, including but not limited to fluorescence imaging systems, optical imaging systems, or a combination of imaging systems. For example, to image in fluorescence, one or more targets of interest (e.g., within or on a sample where such targets of interest may contain a fluorescent material, which may be located on a sample platform) is illuminated by an optical signal having a first spectral content (excitation light) where a portion of such a signal is absorbed by at least part of the target of interest and emitted as optical signal of a second spectral content (emission light). The emission light is then detected by a detection system as a measure of the amount of the fluorescent material present in the one or more targets of interest within or on a sample at the designated, illuminated location. Imaging an area of a sample containing one or more targets of interest comprising fluorescent material, therefore, requires excitation light delivered to the targets of interest within or on a sample, an imaging system that collects light from the one or more targets of interest and projects the collected light onto an optical detector (e.g., detector array), and a means to separate the emitted fluorescence light from the portion of excitation light that makes its way through the imaging system. The latter, typically, includes one or more optical interference filters.

Wide-Field imaging, as considered herein, includes collecting light from a contiguous area and projecting it onto a detector array, such as a CCD or other detectors having an array of sensing locations or pixels, at the same time in a way that preserves the relative locations of each point within the contiguous area. This is different from collecting light from one point at a time and sequentially scanning to a different point in order to cover a larger area, i.e. point scan imaging. It is also different from collecting light from a large area and condensing the total amount of light onto a detector and reading it as total signal. The latter is common for many measurement techniques that do not require specific location information.

One skilled in the art will understand that many types of useful sensors or detectors and arrays of sensors, such as but not limited to CCD and CMOS sensors can be used. Other useful sensors might include photodiodes, avalanche photodiodes, silicon photomultiplier devices, an array of photomultiplier tubes, a focal plane array, etc.

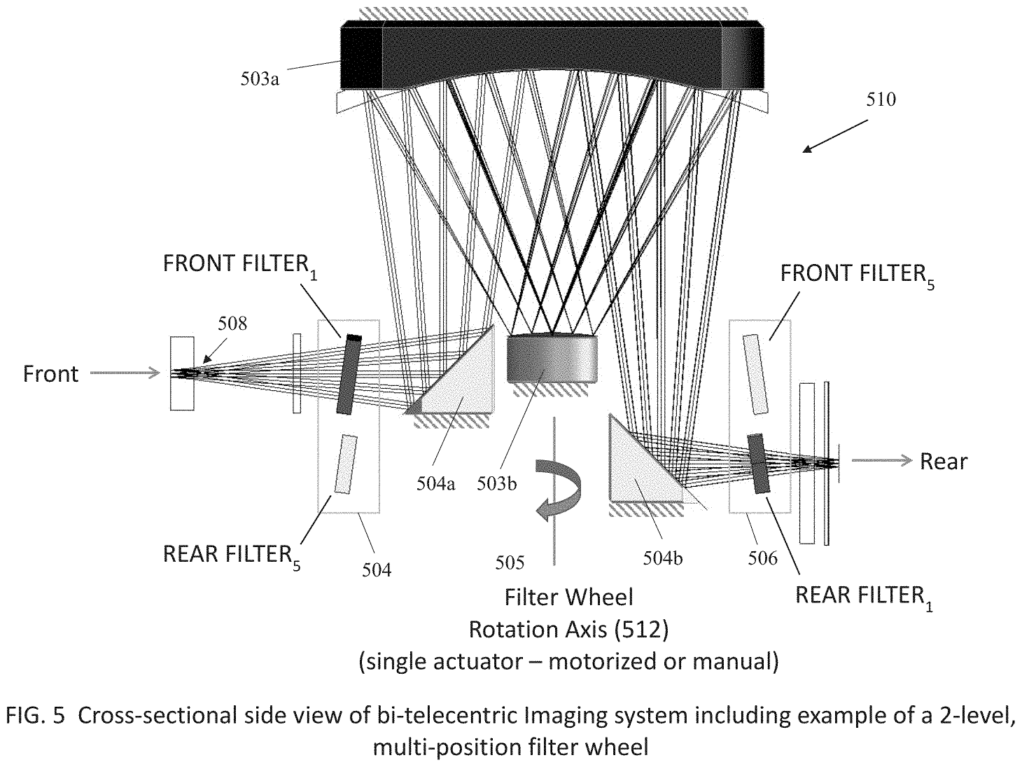

FIG. 5 illustrates a side view of a bi-telecentric imaging system 510 according to an embodiment. Telecentric imaging refers to the case where the Principal or chief rays from all the points being imaged are parallel to each other. A design can be telecentric in the object space where the Principal or chief rays are parallel to each other in the space between the first element of the imaging optics and the sample. On the other hand, a design that is telecentric in the image space has its Principal or chief rays between the last element of the imaging optics and the detector array parallel to each other. Additional aspects and features of bi-telecentric imaging and bi-telecentric imaging systems may be found in U.S. Pat. No. 9,541,750, titled “TELECENTRIC, WIDE-FIELD FLUORESCENCE SCANNING SYSTEMS AND METHODS,” which is incorporated herein by reference in its entirety.

The bi-telecentric imaging system shown in FIG. 5 leverages the symmetry present in the mirror system to create both object-space and image-space telecentric areas, enabling placement of both a rejection filter and an emission filter as depicted without sacrificing any light collection capability or imaging performance. For example, a rejection filter may be positioned in the object-space telecentric area 504 and the emission filter may be placed in the image-space telecentric area 506. In this manner, all filtering is done with chief rays parallel to each other and distances between chief rays is unchanged when adjusting focus. The magnification of this imaging technique, and therefore location accuracy, is quite insensitive to focus errors and therefore image-to-image or pass-to-pass registration is very robust. In certain aspects, a rejection filter includes one or more filter elements that reject (or filter out) excitation light wavelengths, while allowing other light wavelengths as desired to pass. Similarly, an emission filter includes one or more filter elements that allow emission band wavelengths to pass, while rejecting other wavelengths as desired. Examples of useful filters include notch filters to block most of the excitation light and band-pass filters to further block any residual excitation light leaking through the notch filter.

In the configuration shown, “Front” indicates an object plane, which may include a sample platform configured to hold a target irradiated by light and “Rear” may include a detector, such as a CCD detector array or other imaging device. A light source (not shown) illuminates the sample platform with light. In certain embodiments, the light source may include one or more laser or LED sources, and various light conditioning and/or light guiding optical elements, configured to illuminate a portion of the sample platform facing toward or away the imaging system 510. The light beam (not shown) may be configured to illuminate an area on the sample platform for area imaging applications, or it may be configured to illuminate a line on the sample for line scanning applications. For example, in one embodiment, the light source may include the combined illumination beam 345 from FIG. 3 or the combined illumination beam 445 from FIG. 4.

As shown, the bi-telecentric optical imaging system may include an Offner relay mirror system arrangement comprising a first mirror element 503a having a spherical mirror surface and a second mirror element 503b having a spherical mirror surface, wherein the entry aperture and the exit aperture each comprise a portion of the first mirror element.

From every point on the sample area being imaged, there is a cone of light 508 that includes a chief ray at its center that travels along a first light path and passes through rejection filter in region 504 in a telecentric way; the chief ray is refocused by Offner mirror elements 503a and 503b to the image side where the chief ray travels along a second light path and passes through the emission filter in region 506 also in a telecentric way before it reaches the detector, e.g., detector array, also perpendicularly to it, in a telecentric way. Folding mirrors 504a and 504b (or other mirrors or components configured to re-direct light) are used to redirect the path for ease of packaging and coupling with filters, e.g., a rotatable filter wheel assembly as will be discussed below. For line scanning embodiments, with this imaging system, a strip area can be imaged in optically under fully telecentric filtering conditions. Larger sample areas may be covered by scanning the sample platform or the imaging system to other different areas and stitching all images together to produce a uniform, contiguous image of the desired total area.

In certain embodiments, the bi-telecentric imaging system includes a multi-position filter wheel assembly. For example, the filters in FIG. 5 may be part of a single-level or multi-level, multi-position filter wheel assembly as described in U.S. Provisional Patent Application Ser. No. 62/767,385, filed on Nov. 14, 2018, and US. Patent Application Ser. No. 62/767,385, filed on Nov. 13, 2019, both titled “COMPACT HIGH DENSITY ROTARY OPTICAL FILTER WHEEL ASSEMBLIES,” and which are both hereby incorporated by reference. Rotation of the filter wheel assembly (and hence the filters located in regions 504 and region 506) about the common axis 512 changes the filter configuration; for example, in a first filter configuration a first one of the first filters is positioned in the first light path in region 504 and the corresponding complementary filter is positioned in the second light path in region 506, and in a second filter configuration a second one of said first filters is positioned in the first light path and the corresponding complementary filter is positioned in the second light path.

The rotatable filter wheel assembly 505 may be manually adjustable and/or rotatable using an adjustment mechanism (e.g., including a stepper motor or other actuator) configured to adjust or rotate the filter wheel assembly to the desired filter configuration responsive to a control signal, e.g., responsive to a control signal received from the control system (not shown). The control system module includes a memory and is further adapted to acquire and store image data taken by the light detector of the detector subsystem.

As shown in FIG. 5, the rotatable filter wheel assembly 505 is arranged in a first filter configuration filter where Front Filter₁ is currently positioned in the object-space telecentric area 504 and Rear Filter₁ is positioned in the image-space telecentric area 506. Upon controlled rotation of the filter wheel assembly 505 about the axis 512, different filter positions, and hence different filtering capabilities, may be achieved depending on the filter attributes for each position. For example, upon rotation of the rotatable filter wheel, Front Filter₅ may be positioned in the object-space telecentric area 504 and Rear Filter₅ is positioned in the image-space telecentric area 506. In this configuration, for optical imaging (e.g., fluorescence imaging), it may be desirable that each Front Filter act as a rejection filter to filter out the excitation light and each Rear Filter act as an emission filter. As disclosed herein, the rejection filter may include a notch filter or a long-pass filter, and the emission filter may include a band-pass filter or a long-pass filter. For other imaging applications, the Front Filter and the Rear Filter may include optical filters or other components, e.g., windows, as desired.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

A “target of interest” may include a material or molecule of interest such as a biomolecule. Biomolecules are molecules of a type typically found in a biological system, whether such molecule is naturally occurring or the result of some external disturbance of the system (e.g., a disease, poisoning, genetic manipulation, etc.), as well as synthetic analogs and derivatives thereof (e.g. recombinant). Non-limiting examples of biomolecules include amino acids (naturally occurring or synthetic), peptides, polypeptides, glycosylated and unglycosylated proteins (e.g., polyclonal and monoclonal antibodies, receptors, interferons, enzymes, etc.), nucleosides, nucleotides, oligonucleotides (e.g., DNA, RNA, PNA oligos), polynucleotides (e.g., DNA, cDNA, RNA, etc.), carbohydrates, hormones, haptens, steroids, toxins, etc. Biomolecules may be isolated from natural sources, or they may be synthetic. The target of interest may be, for example, an enzyme or other protein. The target of interest may be a peptide or a polypeptide. The target of interest may be an antibody, antibody-like or a fragment of an antibody. The target of interest may be a nucleic acid molecule. The target of interest may include deoxyribonucleic acids (DNA) or ribonucleic acids (RNA). The target of interest may be a polynucleotide or other polymer. The target of interest may thus be, for example, proteins, nucleic acids, carbohydrates, lipids, or any other type of molecule.

The target of interest may be unmodified or the target of interest may be modified to contain one or more labels. An unmodified target of interest may be visualized through its inherent auto-fluorescent spectral properties during optical imaging. An unmodified target of interest comprising of non-fluorescent or non-excitable material may be visualized through the administration of one or more chemical stains to the sample comprising such unmodified target of interest prior to or during optical imaging. The target of interest may be modified to contain one or more labels through physical conjugation, chemical conjugation, genetic expression, etc. The one or more labels of the modified target of interest may comprise an excitable material. Non-limiting examples of labels include fluorescent materials (e.g. fluorophores or other like materials), phosphorescent materials (e.g. porphyrin or other like materials), bioluminescent materials (e.g. Luciferase expression or other like materials), chromophoric materials (e.g. chromophores or other like materials), etc. Embodiments of label materials of a target of interest may refer to any liquid, solid, or other type of material that absorbs light and re-emits at least a portion of what is absorbed as an optical signal (light) of a different spectral content as a measure of the amount present of that target of interest at that location.

Embodiments of the present invention with optical imaging systems address to imaging targets of interest contained in or on a sample. A “sample” includes and may refer to any liquid, solid, or other type of material that may be comprised of or as, in or on a cell or cells (e.g. in whole or lysed); a slurry or an extraction of cellular components; a tissue or tissues; an organ, organs, organoid or other organ-like materials; invertebrate or vertebrate organisms (i.e. in whole or in part); substrates such as but not limited to western blots, membranes, gels, plastic media, glass media or other media; or any combination thereof.

Exemplary embodiments are described herein. Variations of those exemplary embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A system for combining multi-mode and single-mode illumination beams, the system comprising:
a single-mode laser configured to output an illumination beam having a single-mode profile;
a multi-mode laser configured to output an illumination beam having a multi-mode profile, wherein a beam waist size of the multi-mode profile illumination beam is greater than a beam waist size of the single-mode profile illumination beam;
correction optics configured to reduce the beam waist size of the multi-mode illumination beam to substantially the same size as the beam waist size of the single-mode illumination beam; and
beam-combining optics configured to combine the single-mode illumination beam and the multi-mode illumination beam into a combined illumination beam along a first light path.

2. The system of claim 1, wherein the beam-combining optics are positioned between the multi-mode laser and the correction optics, and between the single-mode laser and the correction optics.

3. The system of claim 1, wherein the correction optics are positioned between the multi-mode laser and the beam-combining optics.

4. The system of claim 1, further comprising beam-shaping optics configured to reshape a profile of the combined illumination beam to a line-shaped profile at a sample plane.

5. The system of claim 4, wherein the beam-shaping optics include one or more of a cylindrical lens, a Powell lens, an engineered diffuser, a cylindrical micro-lens array and a scanning mirror, or any combination thereof.

6. The system of claim 1, further comprising:
beam-shaping optics configured to reshape a profile of the combined illumination beam to a spot-shaped profile at a sample plane; and
a scanning mirror positioned between the beam-shaping optics and the sample plane and configured to controllably scan the spot-shaped illumination profile to form a line-shaped illumination profile at the sample plane.

7. The system of claim 6, wherein the spot-shaped illumination profile is elliptical.

8. The system of claim 1, wherein the correction optics includes one or more of a mirror, a reflective element, a dichroic element, a cylindrical lens, a spherical lens, an aspheric lens, an aperture and a diffractive element, or any combination thereof.

9. The system of claim 1, wherein the illumination beam output by the single-mode laser has a wavelength in the visible wavelength range, and wherein the illumination beam output by the multi-mode laser has a wavelength in the infra-red wavelength range.

10. A system for producing illumination having a line-shaped profile, the system comprising:
one or more single-mode lasers each configured to output an illumination beam having a single-mode profile;
one or more multi-mode lasers each configured to output an illumination beam having a multi-mode profile, wherein a beam waist size of each of the multi-mode profile illumination beams is greater than a beam waist size of each of the single-mode profile illumination beams;
correction optics configured to reduce the beam waist sizes of the multi-mode illumination beams to substantially the same size as the beam waist size of the single-mode illumination beams;
beam-combining optics configured to combine the single-mode illumination beams and the multi-mode illumination beams into a combined illumination beam along a first light path; and
beam-shaping optics configured to reshape a profile of the combined illumination beam to a line-shaped profile at a sample plane.

11. The system of claim 10, wherein the beam-combining optics are positioned between the one or more multi-mode lasers and the correction optics, and between the one or more single-mode lasers and the correction optics.

12. The system of claim 10, wherein the correction optics are positioned between the one or more multi-mode lasers and the beam-combining optics.

13. The system of claim 10, wherein the beam-shaping optics include one or more of a cylindrical lens, a Powell lens, an engineered diffuser, a cylindrical micro-lens array and a scanning mirror, or any combination thereof.

14. The system of claim 10, wherein the beam-shaping optics are configured to reshape a profile of the combined illumination beam to a spot-shaped profile at a sample plane; and wherein the beam shaping optics includes a scanning mirror configured to controllably scan the spot-shaped illumination profile so as to form a line-shaped illumination profile at the sample plane.

15. The system of claim 14, wherein the spot-shaped illumination profile is elliptical.

16. The system of claim 10, wherein the correction optics includes one or more of a mirror, a reflective element, a dichroic element, a cylindrical lens, a spherical lens, an aspheric lens, an aperture and a diffractive element, or any combination thereof.

17. The system of claim 10, wherein the illumination beams output by the one or more single-mode lasers each has a wavelength in the visible wavelength range, and wherein the illumination beams output by the one or more multi-mode lasers each has a wavelength in the infra-red wavelength range.

18. An imaging system comprising:
a sample platform configured to hold a sample; and
a light source subsystem that illuminates the sample platform,
the light source subsystem comprising:
a single-mode laser configured to output an illumination beam having a single-mode profile;
a multi-mode laser configured to output an illumination beam having a multi-mode profile, wherein a beam waist size of the multi-mode profile illumination beam is greater than a beam waist size of the single-mode profile illumination beam;
correction optics configured to reduce the beam waist size of the multi-mode illumination beam to substantially the same size as the beam waist size of the single-mode illumination beam;
beam-combining optics configured to combine the single-mode illumination beam and the multi-mode illumination beam into a combined illumination beam along a first illumination light path; and
beam-shaping optics configured to reshape a profile of the combined illumination beam to a line-shaped profile at the sample platform; and
a detector subsystem for detecting light from the sample platform, and comprising a light detector having an array of sensing locations;
an optical imaging system comprising optical elements configured to receive light from the sample platform along a first detection light path and to pass or to direct the received light to the light detector along a second detection light path.

19. The imaging system of claim 18, wherein the optical imaging system comprises a bi-telecentric optical imaging system including imaging optics arranged and positioned such that a first telecentric space exists in the first detection light path between the sample platform and the entry aperture, wherein Principal rays from a plurality of field points on the sample platform are parallel to each other when passing through a first filter in the first detection light path, and such that a second telecentric space exists in the second detection light path between the light detector and the exit aperture, wherein the Principal rays from the plurality of field points are parallel to each other when passing through a second filter in the second detection light path.

20. The imaging system of claim 19, wherein the bi-telecentric optical imaging system comprises an Offner relay mirror system arrangement comprising a first mirror element having a spherical mirror surface and a second mirror element having a spherical mirror surface, wherein the entry aperture and the exit aperture each comprise a portion of the first mirror element.

21. The imaging system of claim 18, wherein the system is a fluorescence imaging system, wherein the sample includes one or more targets of interest that comprises fluorescent material, and wherein at least one of the multi-mode illumination beam and the single-mode illumination beam has a wavelength in an absorption band of the fluorescent material comprised within the target of interest.

22. The imaging system of claim 18, wherein the sample includes one or more targets of interest, and wherein the optical imaging system is configured to image the one or more targets of interest onto the light detector.

23. The imaging system of claim 18, wherein the beam-shaping optics are configured to reshape a profile of the combined illumination beam to a spot-shaped profile at the sample platform; and wherein the beam shaping optics includes a scanning mirror configured to controllably scan the spot-shaped illumination profile so as to form a line-shaped illumination profile at the sample platform.

24. The imaging system of claim 23, wherein the light source subsystem includes an aperture element disposed between the scanning mirror and the sample platform, the aperture element including an aperture and configured to prevent the combined illumination beam from illuminating the sample platform when the scanning mirror is oriented at an end of a scan range.

25. The imaging system of claim 18, further including a control system module comprising at least one processor, wherein the control system module is communicably coupled with and adapted to control operation of the light source subsystem and the detector subsystem.

26. The imaging system of claim 18, wherein the beam-shaping optics includes a scanning mirror configured to controllably scan the line-shaped illumination profile along the sample platform.

27. The imaging system of claim 26, wherein the light source subsystem includes an aperture element disposed between the scanning mirror and the sample platform; the aperture element including an aperture and configured to prevent the combined illumination beam from illuminating the sample platform when the scanning mirror is oriented at an end of a scan range.

28. The imaging system of claim 18, wherein the light source subsystem includes a neutral density filter control mechanism configured to dispose a neutral density filter in or out of the first illumination light path between the scanning mirror and the sample platform in response to a control signal.
